(19) United States
(12) Patent Application Publication
(10) Pub. No.: US 2015/0294735 A1
(43) Pub. Date: Oct. 15, 2015

(54) UNIT TESTING OF DATA STORAGE DEVICES AT A DATA CENTER

(71) Applicant: Seagate Technology LLC, Cupertino, CA (US)

(72) Inventors: Kaizhong Gao, North Oaks, MN (US); Dave Aune, Eagan, MN (US)

(73) Assignee: Seagate Technology LLC, Cupertino, CA (US)

(21) Appl. No.: 14/251,054

(22) Filed: Apr. 11, 2014

(51) Int. Cl. G11C 29/08; H04L 29/08

(52) U.S. Cl. CPC G11C 29/08; H04L 67/1097

(57) ABSTRACT

A plurality of data storage devices from a storage device provider are received, at a data center. A tester is received at the data center via the storage device provider. A unit test of the data storage devices is performed at the data center via the tester contemporaneously with using the data storage devices in the data center.

### BACKGROUND

The present disclosure is generally related to the manufacturing, delivery and total cost of ownership (TCO) of persistent storage (e.g. HDD's, SSD's) and data center equipment. An increasing number of data centers being built to satisfy the demands of popular Internet services such as social media, cloud computing and the like. Large data centers may cover hundreds of thousands of square feet, and may house a similar number of individual computing nodes. These nodes may each have a dedicated amount of persistent data storage, e.g. provided by storage arrays. The manufacturing and delivery of a large number of individual storage devices used in such arrays is a capital-intensive, labor-intensive and cost-intensive endeavor. Also, the large number of individual storage devices used in such arrays makes assembly and test of the arrays within a data center a labor- and cost-intensive endeavor.

### SUMMARY

The present disclosure is related to unit testing of data storage devices at a data center. In one embodiment, a method involves receiving, at a data center, a plurality of data storage devices from a storage device provider. A tester is received at the data center via the storage device provider. A unit test of the data storage devices is performed at the data center via the tester contemporaneously with using the data storage devices in the data center.

In another embodiment, a method involves providing a tester for use in testing a plurality of data storage devices at a data center. The plurality of data storage devices are shipped to the data center, the devices undergoing minimal final testing prior to the shipping. Testing of the data storage devices is facilitated at the data center via the tester contemporaneously with use of the data storage devices by the data center.

In another embodiment, a method involves shipping a plurality of data storage devices and a testing apparatus from a storage device provider to a data center. A unit test on the data storage devices is performed at the data center via the testing apparatus in proximity to a higher-level assembly. A first portion of the data storage devices that pass the testing are assembled into the higher-level assembly. The testing apparatus facilitates the assembling of the first portion of the data storage devices

These and other features and aspects of various embodiments may be understood in view of the following detailed discussion and accompanying drawings.

### BRIEF DESCRIPTION OF THE DRAWINGS

In the following diagrams, the same reference numbers may be used to identify similar/same/analogous components in multiple figures.

FIG. 1 is a block diagram illustrating a process used in integrating devices to a network data center;

FIG. 2 is a block diagram of illustrating real-time test and assembly according to an example embodiment;

FIG. 3 is a block diagram of a testing system and apparatus according to an example embodiment; and

FIGS. 4 and 5 are flowcharts illustrating methods according to example embodiments.

### DETAILED DESCRIPTION

The present disclosure is related to large-scale, data processing and storage centers. For purposes of this disclosure, a data center refers to a collection of networked computers (e.g., servers, storage arrays) that are situated in a facility and used to provide general-purpose or special-purpose computing tasks on behalf of one or more customers. This type of service may be referred to as cloud computing, clustered computing, distributed computing, software as a service, etc. Generally, such systems share some common characteristics, such as large numbers of similar/identical computing nodes, large scale network interconnections, automated monitoring and control of computing nodes, specialized cooling and power distribution, etc. While data centers may be sometimes referred to Internet data centers, the computing nodes need not be made accessible via the public Internet.

The assembly and operation of a network data center involves significant planning and effort. Although the computing equipment itself may include commercial, off-the-shelf components, the scale and complexity of the installation requires up-front analysis to ensure that the system performs up to its potential. Many aspects of the data center may require custom design, such as power distribution, cooling, management software, etc. However, even where a large number of pre-manufactured devices are used, such as data storage devices, integration of these devices into the system may require careful planning

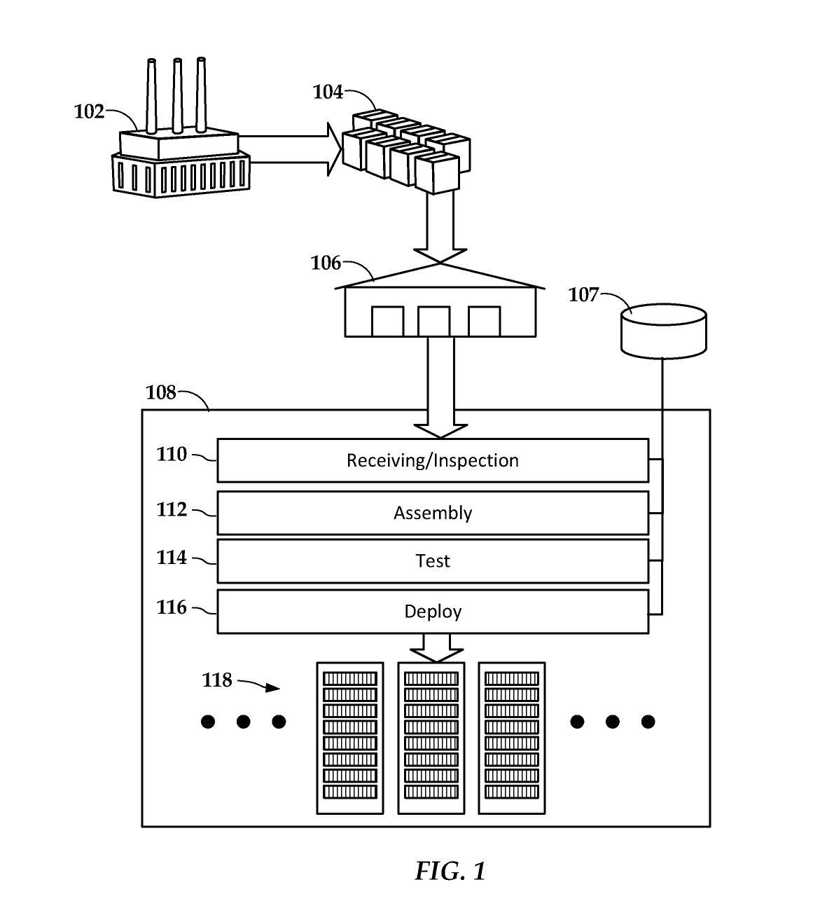

In the present disclosure, methods, systems and apparatuses are described that can be used to facilitate integration of data storage devices into a network data center. These data storage devices may include hard disk drives (HDD), solid-state drives (SSD), hybrid drives, optical drive units, magnetic tape units, and any other type of persistent data storage device that may be used in significant quantities in the operation of a network data center. For purposes of this disclosure, data storage devices may also be referred to as “drives.” An example of a process used in integrating data storage device to a network data center is shown in the block diagram of FIG. 1.

Generally, a manufacturer 102 (or other provider) of storage devices provides line replaceable units (LRUs) 104, which may include bare data storage devices (e.g., HDD, SSD), specially-enclosed storage devices (e.g., hard drive in a hot-swappable case), subassemblies of multiple drives, etc. The LRUs are shipped to a network data center 108, e.g., directly and/or via a distribution center 106. Upon arrival at the network data center 108, the LRUs 104 may be processed at various stations, such as receiving/inspection 110, assembly 112, test 114, and deployment 116.

Generally, the receiving/inspection station 110 performs a physical inspection to ensure the LRU's 104 are what was ordered and show no outside evidence of physical damage. The receiving/inspection station 110 also keeps records that facilitate tracking the LRUs 104 in the data center 108, e.g., via inventories, parts lists, etc. The records may be stored in a database 107. Once processing is finished at the receiving/inspection station 110, the LRUs 104 may be placed in a staging area for use by the assembly station 112.

At the assembly station 112, the LRUs 104 are combined with other equipment (e.g., chassis, shelves, cables, fans, ducts, sensors, peripheral boards, etc.) to form higher-level assemblies. The assembly station 112 may use automation (e.g., robots) and human labor. The higher-level assemblies may include computer housings, multi-computer chassis (e.g., blade server enclosure), racks, etc. Generally, the LRUs 104 operate as a system within the higher-level assembly, and may require different testing, e.g., assembly-level integration testing at testing station 114. The composition of the higher-level assemblies (e.g., parts lists, serial numbers) may also be stored in the database 107, as well as results of the integration testing.

The testing station 114 may perform memory checks, e.g., writing to memory with known data and reading back to ensure integrity. This may be performed for volatile and non-volatile memory. Other components may have similar testing performed, such as network cards, storage controllers, processors, etc. These tests generally ensure there are no component failures. Other tests that may be performed at testing station 114 include benchmarking and performance testing, e.g., measuring data throughput of memory, network, and input/output bus lines, etc. This type of testing generally tests the system overall, e.g., simulating computing tasks such as web service requests and database operations. This verifies that operational components are performing within specification.

As indicated by deployment station 116, the assembly-level components are in their final deployed location, as indicated by racks 118. The deployment station 116 may include systems used to monitor performance of the data center 108 as it is being used. The deployment station 116 may track ongoing performance as well as operational failures, and data describing operations and failures of the deployed system may also be put in database 107.

In some data centers, the assembly station 112 may be located at least in part off-site, e.g., a vendor may provide partial or full racks, and the racks may be shipped to the data center 108 and installed. For purposes of the following discussion, such off-site facilities may be considered part of the assembly station 112, such as where the higher-level assemblies are custom-made for the data center 108.

For LRUs 104 such as data storage devices, the data storage devices may be fully tested by the manufacturer 102, shipped to the data center 108, where they may not be activated again until such time as they are assembled, configured, and integration tested at assembly and testing stations 112, 114. In large-scale data centers, this may result in some inefficiencies. For example, some percentage of data storage devices that pass testing at the manufacturer may fail on first use or soon thereafter. This may involve replacing the failed part, generating a return request along with further inventory and shipping operations (e.g., staging, packaging, tracking) The return information may only provide limited information to the storage device manufacturer regarding the symptoms and context of the failure.

For some entities, such as a manufacturer that assembles computers for home or business use, the variety of end-products produced may mean that all device failures (e.g., data storage, motherboards, processors, network interface cards) can be treated similarly, e.g., relying on manufacturer testing of individual components, then weeding out initial failures through integration test and burn-in. Devices that fail these tests are shipped back to distributers/manufacturers for exchange or credit. This return/exchange may also be similarly implemented for in-service failures, e.g., warranty repairs. The device manufacturer that receives the returned parts may attempt to repair/refurbish, scrap, and/or analyze returned parts.

A large-scale data center may generally use a smaller variety of parts than a general-purpose computer manufacturer, and those parts may be deployed into a more controlled and predictable end-use environment. For these and other reasons, the data center may be able perform unit-level testing of data storage devices on-site. This on-site unit testing may be done instead of the device manufacturer performing the tests before shipping. The data center may perform the same unit tests that would have been performed by the manufacturer, but integrates this testing with assembly of the data center units (e.g., racks). This can reduce costs for both manufacturers and data center builders/operators, and may also lead to more reliable components and systems.

In embodiments described below, methods and systems involve the manufacturer 102 shipping data storage devices to the data center 108 without performing full qualification testing. The data storage devices may have some minimal level of testing done, e.g., power on self-test, validate read/write functionality, but otherwise are not given the level of testing that would normally be performed on a shipping drive. Instead, the data center 108 is provided with the drive testing equipment that can be used to fully test the data storage devices on-site just before (or during) assembly. This concept, known as real-time test, real-time assembly, and real-time diagnostic/repair/return, can offer benefits to both the manufacturer 102 and data center 108.

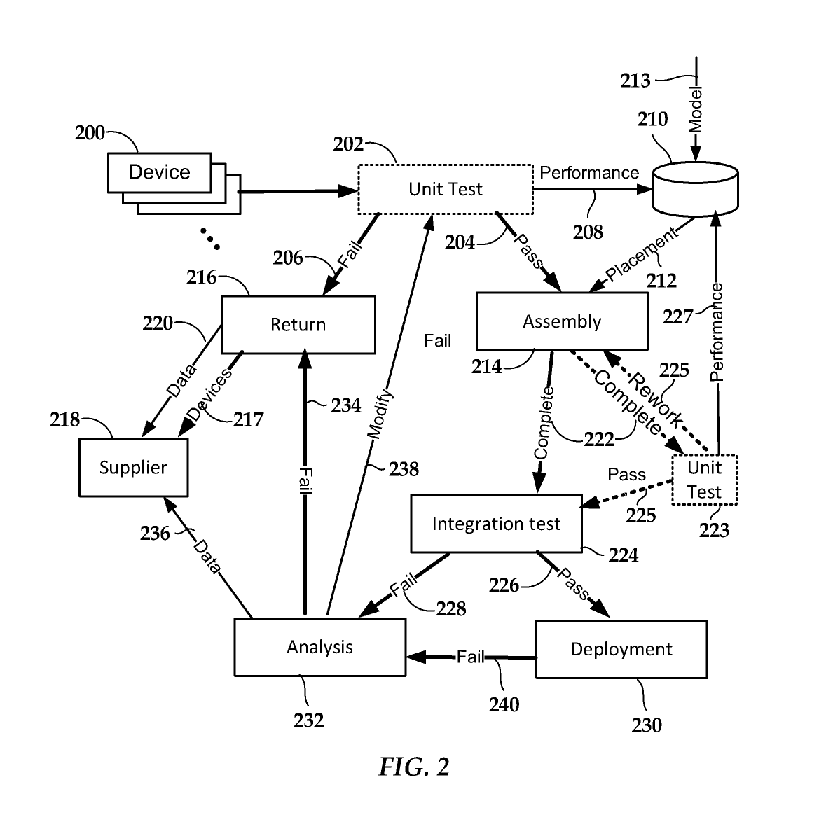

A more detailed example of how real-time test and assembly can be implemented is shown in the block diagram of FIG. 2. Storage devices 200 are received at a data center. The devices 200 have had minimal testing at a manufacturer, and may be placed in a staging area in preparation for real-time test and assembly. For example, the staging area may include a fixture that holds the bare drives and allows a robot to pick and place the drives on a tester in preparation for unit test 202. The unit test 202 may be equivalent to a final test performed by a manufacturer of the storage devices 200, but in this case are performed by agents of the data center, e.g., via an agreement/contract between the manufacturer and data center builder. In another arrangement, the server racks into which the drives are assembled may itself serve as a test fixture. As such, unit test 204 may be performed after assembly 214, e.g., before integration test 224, which is also performed on higher-level assemblies. For example, the supplier 218 may provide server software that can be used to perform unit testing in after the devices 200 have been assembled into a higher-level assembly (e.g., server racks).

It should be noted that the storage device manufacturer may perform different unit tests depending on the target market for the storage devices. For example, enterprise storage devices may have configurations and tests that emphasize higher reliability over capacity; storage devices for general consumer use may use less expensive testing regimes and emphasize high capacity; storage devices targeted for high-performance markets (e.g., gaming, graphics processing) may be tested to ensure some level of performance (e.g., speed) is met. By allowing the data center to specify their own criteria for unit testing 202, the data center may be able to increase performance and/or reduce cost of the overall system by specifying their own pass/fail criteria instead of using criteria that may have been formulated for a broader market.

The unit testing 202 results in a first portion 204 of the storage devices 200 that pass unit test 202 and a second portion 206 of the storage devices 200 that fail unit test 202. In either event, the results of the unit testing 202 may be added to a database 210 as performance data 208. Such performance data 208 may include, among other things, bit-error rates for test reads and writes, seek times, read and write throughput, effects of vibration on seeking and tracking, failure modes, etc. The performance data 208 may have many uses, including statistical analyses of storage devices and used in assembly 214, as indicated by placement data 212.

The portion of storage devices 204 that pass unit test may immediately be assembled into a higher-level unit at assembly 214, such as a storage array, server array, server rack, etc. The assembly 214 may be performed in cooperation with the testing apparatus. For example, the testing apparatus may control robotic connection and disconnection from the tester, followed by robotic placement of storage devices 200 into the higher-level assembly. Placement data 212 may be used by the robots to decide where to place the storage devices into the higher-level assembly, or similar information may be provided to people performing the assembly in cases where robots are not used.

The placement data 212 may be used in cases where the higher-level unit has location-dependent characteristics, such that successfully tested storage devices 204 having particular performance or capacity may be placed in particular locations. For example, some locations may be subject to higher levels of heat or vibration due to nearby components (e.g., fans, ducting, processors), and so if unit testing 202 indicates a subset of the storage devices 204 are more or less thermally or mechanically robust, then those devices may be placed accordingly, as dictated by the placement data 212.

The placement data 212 may be generated by the performance data 208, together with a system model 213. The system model 213 may be explicitly defined, or may be determined experimentally via a feedback loop using various stages of the process shown in FIG. 2. For example, for an initial set of higher-level assemblies, storage devices 204 may be placed without any consideration of placement data 212. After a number of higher-level assemblies have been tested and/or deployed, soft or hard failure data may be used to correlate subsequent performance data measured during test/deployment with other data, such as location, environmental conditions, etc. These correlations may be used to select subsequent storage devices 204 for locations and/or end-use conditions based on performance data 208.

Other factors may dictate placement data 212 such that certain data storage devices 204 are placed in particular locations. For example, drive arrays may be partitioned into operating system and user data portions, each having different requirements as far as capacity, speed, random versus sequential data access, reliability, etc. The drive arrays may be arranged as redundant arrays of inexpensive disks (RAID), in which some partitions of the disks may be used for different uses, such as parity or user data. The placement data 212 may be used to select data storage devices 204, or partitions within particular drives, that may be used for different storage applications or RAID configurations. The placement data 212 may also be used to customize the firmware of the data storage devices 204. Customized/tuned firmware may be used to alter the balance between design parameters, such as reliability versus capacity or performance. The testing apparatus may automatically choose from two or more firmware versions based on an intended placement within the drive array or other assembly.

The apparatus that performs unit test 202 may also provide additional configuration of the data storage devices 204 in a way that is specific to the data center and streamlines the assembly 214. For example, the data storage devices 204 may be partitioned as needed by the data center, e.g., with different operating system and user data partitions, RAID partitions, etc. The data storage devices 204 may be formatted either by the unit testing apparatus or under control of the unit testing apparatus after at least partial assembly to a higher-level assembly. Formatting may at least involve installing a file system on one or more data storage devices 204 usable by a host operating system. The file system may optionally be verified after formatting, e.g., ensuring integrity of the data structures and storage units used by the file system. Other data may also be installed on the data storage devices 200 via the unit test apparatus, such as drivers, operating systems, disk images, etc.

The data storage devices 206 that fail the unit testing 202 are sent a return queue/process 216. Generally, the return process 216 involves providing a collection and processing area in preparation for returning failed devices 217 to supplier 218. This may also involve sending detailed data 220 collected during unit test 202 and elsewhere. This data 220 may be stored in the failed devices 217 themselves by the testing apparatus, assuming the failure does not preclude storing any data on the storage device, e.g., in a region reserved for operational data. In other cases, the test data 220 may be available via a network. For example, the unit test apparatus may be directly accessible via a wide area network, or be configured to upload data to an intermediary server that is accessible by the supplier 218. The test data 220 may also provide other data used in sending back the devices 217, such as invoices, parts lists, purchase order numbers, etc.

After completion of the assembly, an integration test 224 of the assembled unit 222 may be performed. The integration test 224 may involve running simulated tasks such as web service requests, database transactions, file access operations, distributed computing tasks, etc. The integration test 224 may be performed on a single assembly, e.g., a rack of servers, or multiple assemblies, e.g., data storage racks, computing racks, etc. If the assembly passes 226 the integration test 224, it may be placed into deployment 230, e.g., regular operation of the data center. If the assembly fails 228 the integration test 224, further analysis 232 is performed. The analysis 232 may at least involves identifying a component or component that caused the failure, repair of the issue, performing the integration test 224 until the assembly passes 226. As seen by failure condition 240 occurring after deployment 230, the analysis 232 may be used similarly for deployed components and assemblies that experience in-service failures or malfunctions.

If the analysis 232 determines that a failed or malfunctioning data storage device 234 was involved in the failure, then the failed device 234 is sent to return processing 216 as described above. Also, because the failure occurred in a higher-level assembly (e.g., in integration test 224 or deployment 230), there may be additional data 236 that may be sent to the supplier 218 regarding the context of the failure, e.g., operating conditions under which the failure occurred, other equipment used with the failed storage device, time in service, etc.

Data obtained via the analysis 232 may also be used to modify 238 parameters for unit test 202. For example, if a high level of failures 228, 240 can be correlated to some test property of the data storage devices 204, then the criteria for passing the unit test 202 can be tightened. Similarly, if a lower level of failures 228, 240 than predicted occur due to the storage devices 204, then criteria for passing the unit test 202 can be loosened. As previously noted, the modification data 238 may also be used to create and/or adapt the system model 213, as well as affecting drive configuration (e.g., firmware versions).

As noted above, a dedicated testing apparatus may not be needed to perform unit test 202. For example, a tester in the form of software and/or rack mountable hardware may be provided from the supplier 218. All of the received devices 200 may proceed directly to assembly 214 after receipt at the data center. After completion of assembly 222 (or as part of assembly), the devices are subjected to a unit test 223 in the rack (or other higher-level assembly) by the aforementioned tester. A portion of the devices 225 that pass unit test are subjected to integration test 224 thereafter. While not shown in the diagram, another portion that fail the unit test 223 may be sent to the return queue/process 216 as described above for unit test 202. If some storage devices fail unit test 223, additional assembly operations, as indicated by rework path 229, may be performed to replace the failed devices.

As with the pre-assembly unit test 202, the post-assembly unit test 223 may obtain performance data 227 that can be used as described above. For example, if the performance data 227 indicates that better performance may be had by relocating some storage devices within the completed assembly via rework path 225. In such a case, the assembly 214, unit test 223, and integration test 224 can be performed at the same station, and the rework described above (e.g., replacing devices that fail unit test, relocating devices) can be performed robotically.

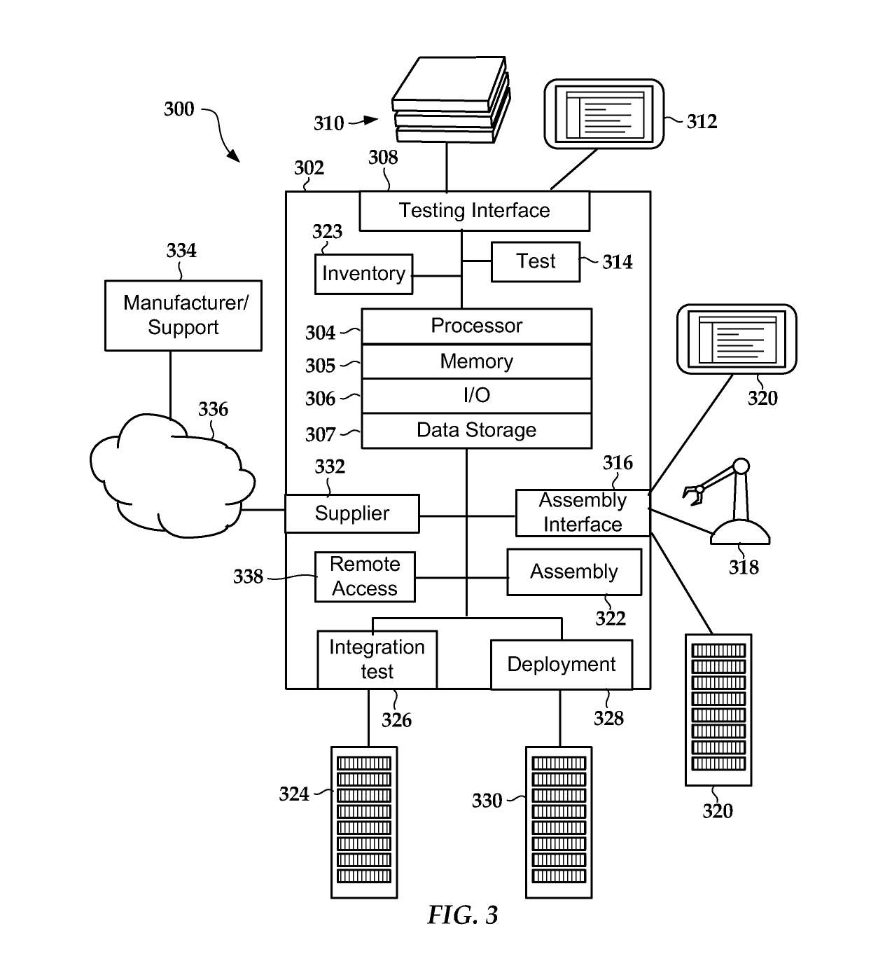

In reference now to FIG. 3, a block diagram illustrates a test system 300 according to an example embodiment. The system 300 includes a tester 302, which may include conventional computing hardware such as a processor 304, memory 305, input/output devices 306 (e.g., network interfaces), and data storage 307 (e.g., hard drive file system, database). The hardware components 304-307 may be in a single chassis, or be distributed between multiple physical devices. In one embodiment, the tester 302 includes a dedicated testing apparatus that includes at least some of the hardware components 304-307. In another embodiment, the storage device vendor may provide software (e.g., in the form a non-transitory computer readable medium) for testing, in which case the hardware components 304-307 may be part of the higher-level assembly (e.g., server rack) into which storage devices are assembled. In either embodiment, the tester 302 includes interfaces and associated functional modules that facilitate testing data storage devices as part of real-time assembly at a data center facility.

The tester 302 includes a drive testing interface 308 that facilitates testing data storage devices 310. The testing interface 308 may include mechanical, electrical, and software interfaces that facilitate physically attaching the drives 310 during the test, electrically coupling the host interface (e.g., SATA, SaS, SCSI) of the data storage devices 310 to busses of the tester 302. The testing interface 308 may also provide a user interface 312 that facilitates user control of some aspects of testing. The testing interface 308 utilizes electrical and software protocols that facilitate communicating with the data storage devices 310. The protocols may include host protocols and testing protocols, the latter accessing special functionality and reserved storage regions of the data storage devices 310. The testing interface 308 is used by a testing module 314 that performs unit tests on the storage devices 310 as described herein.

An assembly interface 316 facilitates assembly operations that are performed contemporaneously with unit test. For example the assembly interface 316 may control a robot 318 that both facilitates unit test (e.g., placing data storage devices 310 in mechanical mounts of testing interface 308 and initiating tests afterwards) and then assembles the tested devices into assemblies 320. An assembly module 322 can coordinate these activities, as well as performing other recordkeeping. For example, lists of parts used in assemblies 320 can be kept in an inventory database 323, along with lists of parts that fail unit test. Test results in all cases can be stored in a test database, e.g., in storage 307.

After the assemblies 320 are complete, they may be subject to additional integration testing, as indicated by test assemblies 324 which are in the process of integration test. Results of the integration tests can be communicated to the apparatus 302 via an integration test interface 326. The integration test data can be used, e.g., to adjust criterion used by the unit test module 314. Similarly, a deployment interface 328 can communicate similar information about deployed assemblies 330 that can be used by unit test module 314 and elsewhere.

A supplier interface 332 facilitates data access by an outside entity 334 such as manufacturer or technical support via a wide-area network 336. The supplier interface 332 may facilitate some level or remote access by the entity 334 for purposes such as providing technical support, troubleshooting drive issues, updating software/firmware, coordinating return shipments, documenting device failures, etc. A remote access module 338 may facilitate remote access for these purposes, as well as preventing network access to other proprietary data. The remote access module 338 may reside in a computing node that does not have access to the local networks of the data center.

Besides providing support for the data center, the supplier interface 332 may be used to communicate statistics of use to entity 334, such as tracking performance statistics of storage devices 310 whether or not the devices pass testing. This could be part of an agreement between the data center and manufacturer, e.g., in response to discounts on a purchase price for the storage devices 310 and/or test apparatus 302. The use of the tester 302 in the system 300 may also be part of such an agreement. For example, the tester 302 (and other associated devices and software) may be licensed, owned, leased, etc. by the data center for the purposes described herein. The manufacture/support entity 334 may subsidize some amount of the cost of the tester 302 directly, or in the form of discounts on data storage devices 310 sold to the data center.

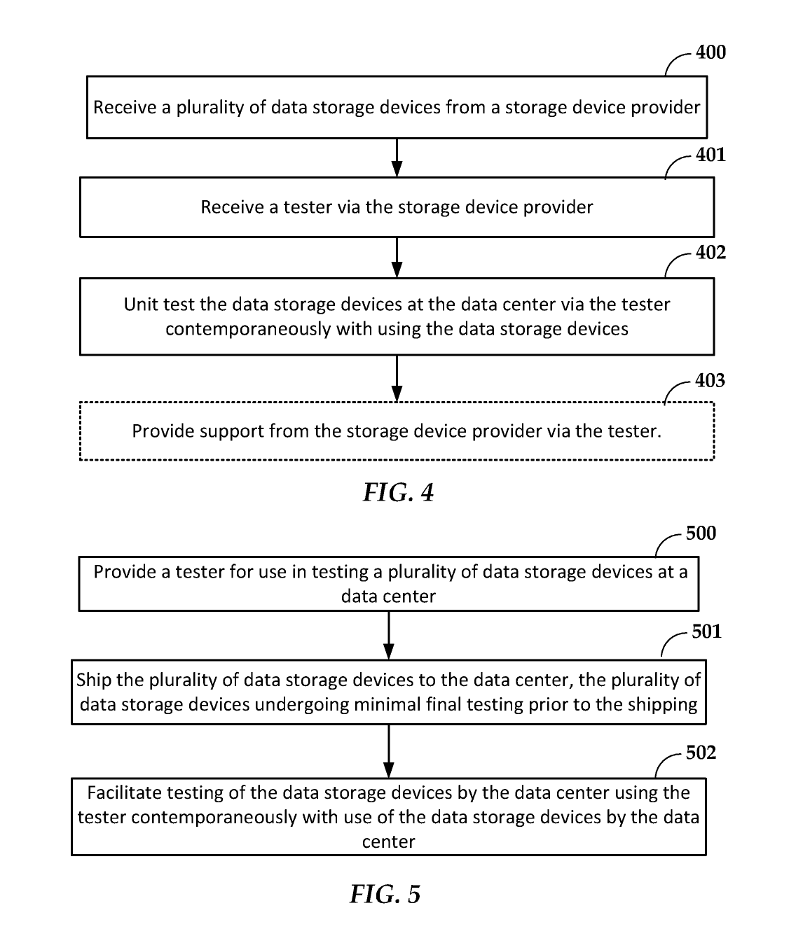

In reference now to FIG. 4, a flowchart shows a method according to an example embodiment. The method involves receiving 400, e.g., at a data center, a plurality of data storage devices from a storage device provider. A tester is also received 401 via the storage device provider. For example, the storage device provider may directly send a testing apparatus or computer-readable medium to the data center, or may initiate an order with a third party to have send the apparatus/medium to the data center. If the tester is embodied at least in part as software, the tester may be downloaded via a network and locally stored in a non-transitory medium at the data center. Generally, the storage device provider is involved in some aspect of providing the tester, and there may be a contract between the parties regarding cost savings, technical support, etc., associated with the receipt and use of the tester.

The data storage devices are unit tested 402 at the data center via the tester contemporaneously with using the data storage devices in the data center. The use of the device may at least involve assembling the data storage devices into a larger assembly, e.g., a rack. The use may occur before or after the unit testing. Use of the storage device may also involve other operations such as integration test and deployment. For some uses such as assembly, the term “contemporaneously” may be on the order of minutes or hours before or after the test, whereas for other uses such as integration test and deployment, contemporaneously may be on the order of days or weeks. Generally, contemporaneous testing and use occurs over a time frame facilitates efficiently collecting and analyzing data of interest to the data center as a whole during assembly and integration of the data center components. The contemporaneous testing and use also streamlines certain aspects related to the build, such as the identification of problems associated with the storage devices, and solutions of those problems.

The method may optionally involve providing 403 support from the storage device provider via the tester. For example, the testing apparatus or software may be accessible to the storage device provider via a wide-area network such as the Internet. The device provider may provide services such as a knowledge base, assistance in troubleshooting, failure analysis, providing firmware updates, etc.

In reference now to FIG. 5, a flowchart illustrates a method according to another example embodiment. The method involves providing 500 a tester for use in testing a plurality of data storage devices at a data center. As part of providing 500 the tester, the tester may be custom-configured to suit needs of the data center, and may be configured to include additional functionality, e.g., to perform additional post-testing configuration such as partitioning, formatting, pre-installing software. The configuration may include adding functionality related to assembly, such as an interface that facilitates combining unit test and assembly via a robot or human operator.

The plurality of data storage devices are shipped 501 to the data center. The plurality of data storage devices undergo minimal final testing prior to the shipping 501. The data storage devices need not be shipped together or at the same time as the tester is provided 500. For example, the tester may be delivered before significant rack assembly occurs to allow time for installation, validation, and modification of the testing apparatus to the data center's specification. Thereafter, data storage devices may be repeatedly shipped in batch sizes corresponding to assembly needs of the data center, thereby minimizing inventory and storage requirements at the data center.

The testing of the data storage devices is facilitated 502 at the data center via the tester. The testing is contemporaneous with use (e.g., assembly, test, deployment) of the data storage devices by the data center. At least part of this facilitation 502 is due to data-center-specific features of the tester made by the storage device provider. For example, the unit test pass/fail criteria, initial drive configuration values, etc., may be customized according to needs of the data center. If the tester includes in-place unit test software, the provider may compile the software for the target platform into which the storage devices are assembled. The provider may provide ongoing support via the tester, e.g., using the aforementioned remote access interface or the like.

The various embodiments described above may be implemented using circuitry and/or software modules that interact to provide particular results. One of skill in the computing arts can readily implement such described functionality, either at a modular level or as a whole, using knowledge generally known in the art. For example, the flowcharts illustrated herein may be used to create computer-readable instructions/code for execution by a processor. Such instructions may be stored on a non-transitory computer-readable medium and transferred to the processor for execution as is known in the art. The structures and procedures shown above are only a representative example of embodiments that can be used to facilitate managing caching in data storage devices as described above.

The foregoing description of the example embodiments has been presented for the purposes of illustration and description. It is not intended to be exhaustive or to limit the inventive concepts to the precise form disclosed. Many modifications and variations are possible in light of the above teaching. Any or all features of the disclosed embodiments can be applied individually or in any combination are not meant to be limiting, but purely illustrative. It is intended that the scope be limited not with this detailed description, but rather determined by the claims appended hereto.

What is claimed is:

1. A method, comprising:
receiving, at a data center, a plurality of data storage devices from a storage device provider;
receiving, at the data center, a tester via the storage device provider; and
performing a unit test of the data storage devices at the data center via the tester contemporaneously with using the data storage devices in the data center.

2. The method of claim 1, wherein the tester comprises testing software, wherein the unit test is performed via a higher-level assembly into which the data storage devices are assembled.

3. The method of claim 1, wherein using the data storage devices in the data center comprises robotically assembling, in cooperation with the tester, a portion of the data storage devices that pass the unit test into a rack.

4. The method of claim 1, further comprising configuring the data storage devices for the data center via the tester.

5. The method of claim 4, wherein configuring the data storage devices comprises installing drivers.

6. The method of claim 4, wherein configuring the data storage devices comprises at least one of partitioning, formatting, and verifying a file system of the data storage devices.

7. The method of claim 1, further comprising determining failure data on a portion of the data storage devices that do not pass the unit test, and sending the failure data to the storage device provider.

8. The method of claim 1, wherein the plurality of data storage devices are given a minimal final test by the storage device provider before being shipped to the data center.

9. The method of claim 1, wherein the tester communicates with the storage device provider from the data center via a wide-area network, the method further comprising providing support from the storage device provider via the tester.

10. The method of claim 1, further comprising:
determining a failure of one of the data storage devices during one of integration test and deployment in the data center; and
using data associated with the failure to modify the unit test.

11. A method comprising:
providing a tester for use in testing a plurality of data storage devices at a data center;
shipping the plurality of data storage devices to the data center, the plurality of data storage devices undergoing minimal final testing prior to the shipping; and
facilitating testing of the data storage devices at the data center via the tester contemporaneously with use of the data storage devices by the data center.

12. The method of claim 11, wherein the tester comprises a dedicated testing apparatus, the method further comprising remotely accessing the dedicated testing apparatus via a wide-area network to support the testing.

13. The method of claim 12, wherein remotely accessing the dedicated testing apparatus via the wide-area network to support the testing comprises at least one of providing failure analysis of the data storage devices and firmware updates to the data storage devices.

14. The method of claim 11, further comprising discounting a purchase price of the plurality of data storage devices in return for the testing at the data center.

15. A method comprising:
shipping a plurality of data storage devices and a testing apparatus from a storage device provider to a data center;
performing a unit test on the data storage devices at the data center via the testing apparatus in proximity to a higher-level assembly; and
assembling a first portion of the data storage devices that pass the testing to the higher-level assembly, wherein the testing apparatus facilitates the assembling of the first portion of the data storage devices.

16. The method of claim 15, further comprising configuring the data storage devices for the data center via the testing apparatus.

17. The method of claim 16, wherein configuring the data storage devices comprises at least one of installing drivers to, partitioning, formatting, and verifying a file system of the data storage devices.

18. The method of claim 15, further comprising determining failure data on a second portion of the data storage devices that do not pass the unit test, and sending the failure data and the second portion of the data storage devices to the storage device provider.

19. The method of claim 15, wherein the plurality of data storage devices are given a minimal final test by the storage device provider before being shipped to the data center.

20. The method of claim 15, further comprising:
determining a failure of one of the data storage devices during one of integration test and deployment in the data center; and
using data associated with the failure to modify the unit test.
